(19) United States
(12) Patent Application Publication
(10) Pub. No.: US 2012/0120567 A1
(43) Pub. Date: May 17, 2012

(54) WRIST WORN DEVICE

(75) Inventor: FANG-KENG HSIEH, Tu-Cheng (TW)

(73) Assignee: HON HAI PRECISION INDUSTRY CO., LTD., Tu-Cheng (TW)

(21) Appl. No.: 13/092,974

(22) Filed: Apr. 25, 2011

(30) Foreign Application Priority Data
Nov. 12, 2010 (CN) 201010541510.1

(51) Int. Cl. H05K 7/00

(52) U.S. Cl. 361/679.01

(57) ABSTRACT

A wrist worn device is provided. The wrist worn device includes a cover, a case, and a rotatable ring. The case is coupled to the cover. The case includes a switch. The rotatable ring is rotatably arranged between the cover and the case. A number of protrusions protrude from the surface of the rotatable ring. Each protrusion can move together with the rotatable ring to a position to actuate the switch.

### BACKGROUND

1. Technical Field

The present disclosure relates to wrist worn devices and, particularly, to an electronic wrist worn device able to receive user input.

2. Description of Related Art

Many wrist worn devices now boast multiple functions beyond traditional wrist watches. For example, wrist worn devices may include MP3, GPS, TV, and phone functions as well as time-telling. However, to be attractive to consumers the wrist worn device should be small, and so the use of touch screens may increase functionality but give rise to user error because of the cramped space of the screen and the number of icons needed for full functionality.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of a wrist worn device in accordance with the present disclosure.

FIG. 2 is an isometric view of a rotatable ring of the wrist worn device in accordance with the present disclosure, viewed from another viewpoint.

FIG. 3 is a partially exploded, perspective view of the wrist worn device in accordance with a first embodiment of the present disclosure.

FIG. 4 is a cross-sectional view of the wrist worn device in accordance with a second embodiment of the present disclosure.

FIG. 5 is a schematic view of an option menu of the wrist worn device in accordance with the present disclosure.

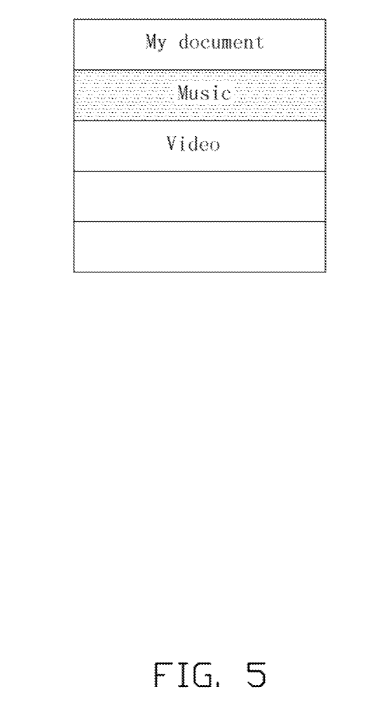

FIG. 6 is another schematic view of the option menu of the wrist worn device in accordance with the present disclosure, showing the items of an audio menu.

### DETAILED DESCRIPTION

Embodiments of the present disclosure will now be described in detail below, with reference to the accompanying drawings.

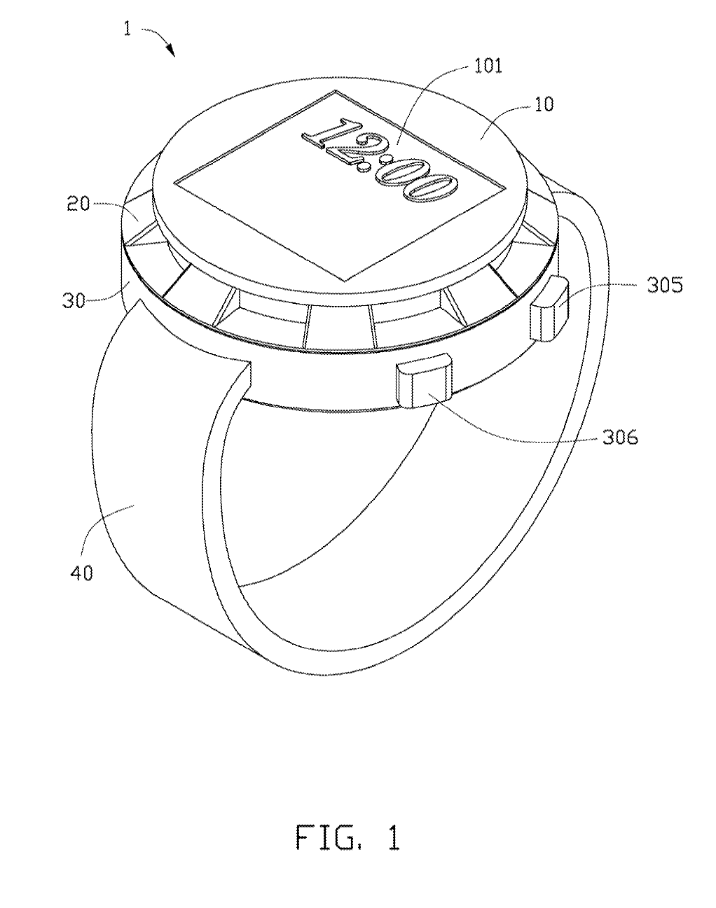

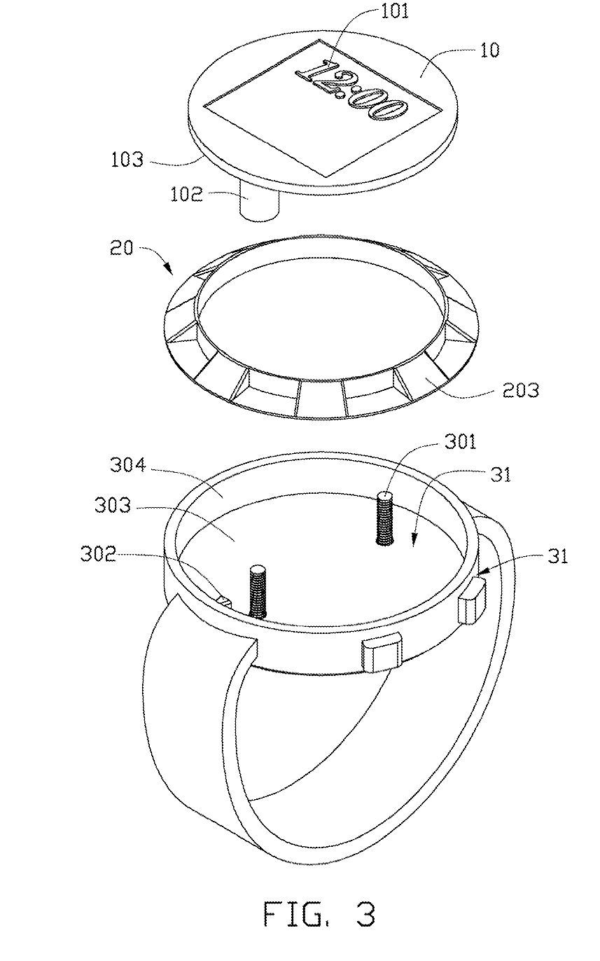

Referring to FIG. 1, a wrist worn device 1 in accordance with the present disclosure is shown. In the embodiment, the wrist worn device 1 is similar in appearance to a wrist watch. The wrist worn device 1 includes a cover 10, a rotatable ring 20, a case 30, and a strap 40. The rotatable ring 20 is rotatably arranged between the cover 10 and the case 30. The cover 10, the rotatable ring 20, and the case 30 cooperatively define a receiving space 31 (see FIG. 3) to receive the required components of the wrist worn device 1. The strap 40 includes two ends connected to the case 30.

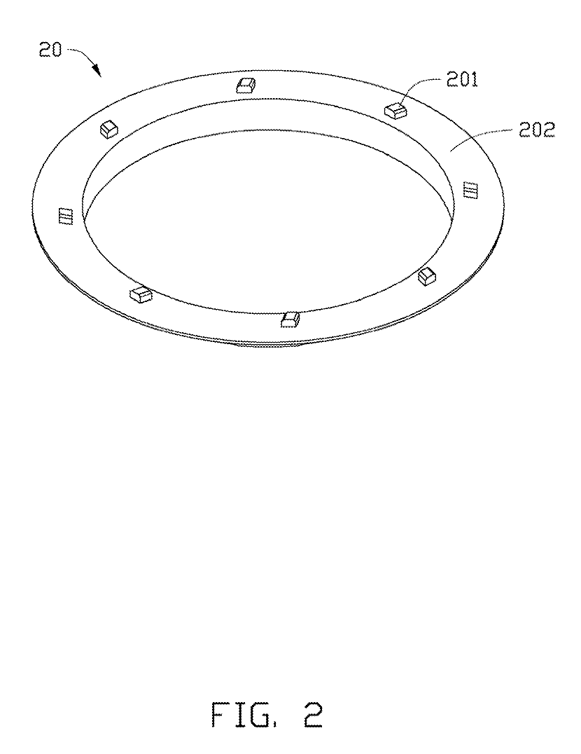

Referring to FIGS. 2-3, a first embodiment of the wrist worn device 1 is shown. The cover 10 includes a display unit 101 and two hollow tubes 102. The display unit 101 is used to display information. The hollow tubes 102 protrude from the bottom surface 103 of the cover 10. Each of the hollow tubes 102 defines a threaded hole. In the embodiment, the distance between the two hollow tubes 102 is slightly shorter than the diameter of the case 30.

The rotatable ring 20 is a circular ring. A number of protrusions 201 protrude from the bottom surface 202 of the rotatable ring 20. In the embodiment, the number of the protrusions 201 is eight. The protrusions 201 are evenly spaced apart from each other around a rotating axis of the ring 20. The outer diameter of the rotatable ring 20 is the same as that of the case 30. The inner diameter of the rotatable ring 20 is larger than the distance between two hollow tubes 102. When the case 30 is assembled to the cover 10, the top surface 203 and the bottom surface 202 of the rotatable ring 20 respectively contact the cover 10 and the case 30. In addition, when the case 30 and the cover 10 are assembled together, a part of the rotatable ring 20 is external to the cover 10, allowing for turning by the user.

The case 30 includes two threaded posts 301 and a switch 302. The threaded posts 301 protrude from the top surface 303. The threaded post 301 can be screwed into the hollow tubes 102, to connect the cover 10 to the case 30.

In the embodiment, the switch 302 is arranged on the inner sidewall 304. In an alternative embodiment, the switch 302 may be arranged on the top surface 303. The switch 302 is arranged in such a manner that the protrusions 201 of the ring 20 can actuate and move over the switch 302. For ease of such movement between the switch 302 and the protrusions 201, each protrusion 201 has rounded side edges. When needed, each protrusion 201 can move together with the rotation of the rotatable ring 20 to a position to actuate the switch 302.

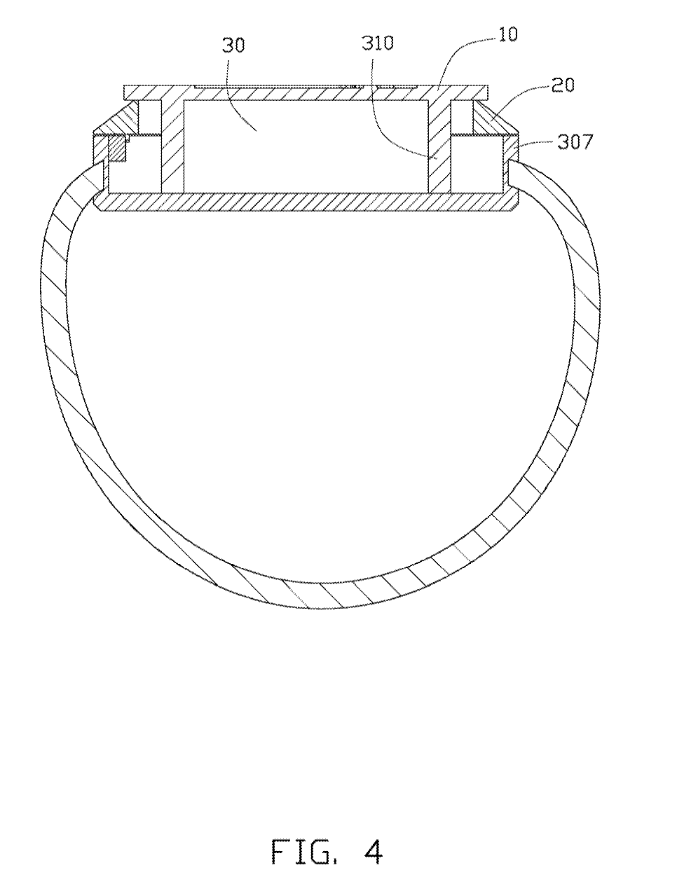

Referring to FIG. 4, a second embodiment of the wrist worn device 1 is shown. The difference between the second embodiment and the first embodiment is described below.

The case 30 includes two protruding posts 310 protruding from the top surface 303 of the case 30. The height of each protruding post 310 is greater than that of the case 30. The case 30 is connected to the cover 10 through the protruding posts 310. In the embodiment, the protruding posts 310 are capable of sticking to the cover 10.

The outer diameter of the rotatable ring 20 is the same as that of the case 30. The inner diameter of the rotatable ring 20 is longer than the distance between two protruding posts 310. When the cover 10 and the base 30 are assembled together, the bottom surface 202 of the rotatable ring 20 contacts the case 30. In addition, as mentioned above, a part of the rotatable ring 20 is external to the cover 10, allowing for turning by the user. As described in the first embodiment, when needed, each protrusion 201 can move together with the rotation of the rotatable ring 20 to a position to actuate the switch 302.

In the embodiments, when the switch 302 is actuated to generate a signal, the processor (not shown) of the wrist worn device 1 executes a preset function in response to the signal from the switch 302, such as controlling a cursor on the display unit 101 to move to the next menu.

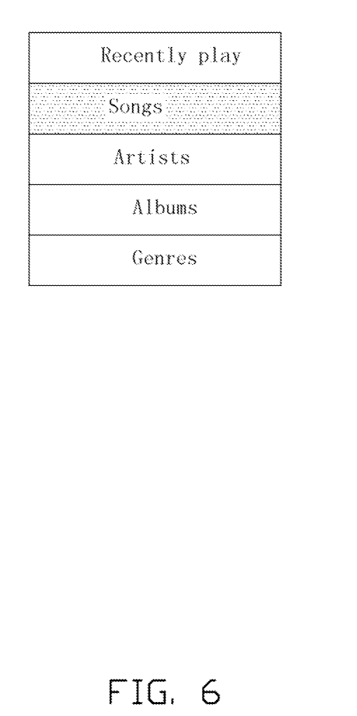

In the embodiments, the case 30 further includes an enter button 305 and a return button 306 (see FIG. 1). The enter button 305 and the return button 306 protrude from the outer sidewall 307 of the case 30. When the cursor of the wrist worn device 1 resides on a selectable menu item on the display unit 101, the enter button 305 can be depressed to execute the function of the menu or expand the menu. For example, when the cursor of the wrist worn device 1 resides on the menu item “music”, the wrist worn device 1 expands the menu item “music” when the enter button 305 is pressed. The display unit 101 then displays a next level menu including for example, “recently played” item, “songs” item, “artists” item, “albums” item, and “genre” item (see FIG. 6). The return button 306 can be pressed to return the previously menu or cannels the function of the selected item.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A wrist worn device comprising:
a cover;
a case coupled with the cover and comprising a switch; and
a rotatable ring rotatably arranged between the cover and the case, and comprising a plurality of protrusions protruding from a bottom surface thereof;
wherein each of the plurality of protrusions is capable of moving together with the rotatable ring to a position to actuate the switch.

2. The wrist worn device as described in claim 1, wherein two hollow tubes protrude from the bottom surface of the cover, two threaded posts protrude from the top surface of the case to be screwed into the hollow tubes to connect the cover to the base.

3. The wrist worn device as described in claim 2, wherein the bottom surface of the rotatable ring contacts the case, a part of the rotatable ring is external of the cover.

4. The wrist worn device as described in claim 3, wherein the outer diameter of the rotatable ring is the same as that of the case, and the inner diameter of the rotatable ring is slightly greater than the distance between the two hollow tubes.

5. The wrist worn device as described in claim 2, wherein the switch protrudes from the bottom surface of the case.

6. The wrist worn device as described in claim 2, wherein the switch protrudes from the inner sidewall of the case.

7. The wrist worn device as described in claim 1, wherein two protruding posts protrude from a top surface of the case, and the cover is attached to the case through the protruding posts.

8. The wrist worn device as described in claim 7, wherein the bottom surface of the rotatable ring contacts the case, a part of the rotatable ring is external of the cover.

9. The wrist worn device as described in claim 8, wherein the outer diameter of the rotatable ring is the same as that of the case, and the inner diameter of the rotatable ring is greater than the distance between the protruding posts.

10. The wrist worn device as described in claim 7, wherein the switch protrudes from the top surface of the case.

11. The wrist worn device as described in claim 7, wherein the switch protrudes from the inner sidewall of the case.

12. The wrist worn device as described in claim 1 further comprising a display unit to display information.

13. The wrist worn device as described in claim 1 further comprising an enter button and a return button, wherein the enter button is used to execute a function menu or expand the menu, and the return button is to return to the previously menu or cannel the function of the menu.
